(19) United States
(12) Patent Application Publication
(10) Pub. No.: US 2026/0190562 A1
(43) Pub. Date: Jul. 2, 2026

(54) SPLICING DISPLAY MODULE AND SPLICING SCREEN

(71) Applicant: TCL CHINA STAR OPTOELECTRONICS TECHNOLOGY CO., LTD., Shenzhen (CN)

(72) Inventors: Xi CHENG, Shenzhen (CN); Junyang NIE, Shenzhen (CN); Hongyuan XU, Shenzhen (CN); Bin ZHAO, Shenzhen (CN)

(73) Assignee: TCL CHINA STAR OPTOELECTRONICS TECHNOLOGY CO., LTD., Shenzhen (CN)

(21) Appl. No.: 19/253,858

(22) Filed: Jun. 29, 2025

(30) Foreign Application Priority Data
Dec. 31, 2024 (CN) 202411999157.X

(51) Int. Cl. H10H 29/24; G02F 1/1333; H10H 29/34; H10H 29/855

(52) U.S. Cl. CPC H10H 29/24; G02F 1/13336; H10H 29/34; H10H 29/8552

(57) ABSTRACT

A splicing display module and a splicing screen are provided. The splicing display module comprises at least two first display panels and a second display panel. Two adjacent ones of the first display panels are spliced with each other to form a splicing area, and the second display panel is disposed corresponding to the splicing area. A first light shielding portion is disposed on a side of a first light-emitting element of the second display panel.

### CROSS-REFERENCE TO RELATED APPLICATION

This application claims priority to and the benefit of Chinese Patent Application No. 202411999157.X, filed on Dec. 31, 2024, the disclosure of which is incorporated herein by reference in its entirety.

### TECHNICAL FIELD

The present disclosure relates to the field of display technology, and in particularly to a splicing display module and a splicing screen.

### BACKGROUND

Liquid crystal display (LCD) devices are currently widely used display products on the market. Its production technology is mature, the product yield is high, the production cost is relatively low, and the market acceptance is high. At present, the demand for various super-large display screens is increasing day by day, and their applications are becoming more and more extensive. Due to technological limitations, the integrated manufacturing process of super-large display screens is difficult and costly. Therefore, adopting splicing screen technology is an effective way to achieve large-size display devices. For example, two liquid crystal display devices are spliced together to form a splicing screen, but there are splicing gaps in the formed splicing screen, which affects the visual effect.

In order to solve the splicing gap of the splicing screen, a light emitting diode (LED) light bar may be installed at the splicing gap to eliminate the splicing gap. However, due to the different light emitting mechanisms of LED and LCD, there is a wide viewing angle chromaticity difference between LED light bar and LCD device, leading to the LED light bar appearing relatively blue at wide viewing angles compared to the LCD device.

### SUMMARY

In a first aspect, an embodiment of the present disclosure provides a splicing display module, which includes:
at least two first display panels, two adjacent ones of the first display panels being spliced with each other to form a splicing area; and
a second display panel disposed corresponding to the splicing area, the second display panel including a driving substrate and at least one light-emitting pixel disposed on the driving substrate, the light-emitting pixel including a first sub-pixel emitting blue light, and the first sub-pixel including a first light-emitting element;
where the second display panel further includes a light shielding member disposed on the driving substrate, the light shielding member includes a first light shielding portion disposed on a side of the first light-emitting element, the first light shielding portion and the first light-emitting element are alternately arranged in a first direction, and the first light shielding portion limits a light exit angle of the first light-emitting element in the first direction.

In a second aspect, an embodiment of the present disclosure further provides a splicing screen, which includes the splicing display module of the above embodiment.

### BRIEF DESCRIPTION OF THE DRAWINGS

In order to more clearly illustrate the technical solutions in embodiments of the present disclosure, the accompanying drawings used for describing the embodiments or the prior art will be briefly introduced below. Apparently, the drawings described below are only directed to some embodiments of the present disclosure, and for those of ordinary skill in the art, other drawings can be obtained based on these drawings without creative efforts.

FIG. 1 is a schematic diagram of comparison of chromaticity difference viewing angle curves between LED and LCD.

FIG. 2 is a schematic view of a planar structure of a splicing display module provided by an embodiment of the present disclosure.

FIG. 3 is a schematic cross-sectional view of FIG. 2 in a direction M-M′.

FIG. 4 is a first schematic view of a planar structure of an arrangement of light shielding members provided by an embodiment of the present disclosure.

FIG. 5 is a schematic diagram of luminance of the second display panel in FIG. 2 at various viewing angles.

FIG. 6 is a second schematic view of a planar structure of an arrangement of the light shielding members provided by an embodiment of the present disclosure.

FIG. 7 is a third schematic view of a planar structure of an arrangement of the light shielding members provided by an embodiment of the present disclosure.

FIG. 8 is a fourth schematic view of a planar structure of an arrangement of the light shielding members provided by an embodiment of the present disclosure.

FIG. 9 is a fifth schematic view of a planar structure of an arrangement of the light shielding members provided by an embodiment of the present disclosure.

FIG. 10 is a sixth schematic view of a planar structure of an arrangement of the light shielding members provided by an embodiment of the present disclosure.

FIG. 11 is a detailed structural schematic view at K in FIG. 10.

FIG. 12 is a schematic cross-sectional structural view along directions M-M′ and N-N′ in FIG. 11.

FIG. 13 is a schematic diagram showing a chromaticity difference viewing angle curve comparison between a second display panel and a first display panel provided by an embodiment of the present disclosure.

FIG. 14 is a schematic flow diagram of a method for improving color shift of a splicing display module provided by an embodiment of the present disclosure.

### DETAILED DESCRIPTION

The following description of the embodiments refers to the accompanying drawings to illustrate specific embodiments which the present disclosure may implement. The directional terms mentioned in the present disclosure, such as “upper”, “lower”, “front”, “back”, “left”, “right”, “inner”, “outer”, “side”, etc., are merely directions with reference to the accompany drawings. Therefore, the directional terms used are intended to explain and understand the present disclosure, rather than to limit the present disclosure. In the drawings, units with similar structures are indicated by the same reference numerals. In the accompanying drawings, for clear understanding and convenient descriptions, some thicknesses of layers and regions are exaggerated. That is, the size and thickness of each component shown in the accompanying drawings are arbitrarily shown, but the present disclosure is not limited thereto.

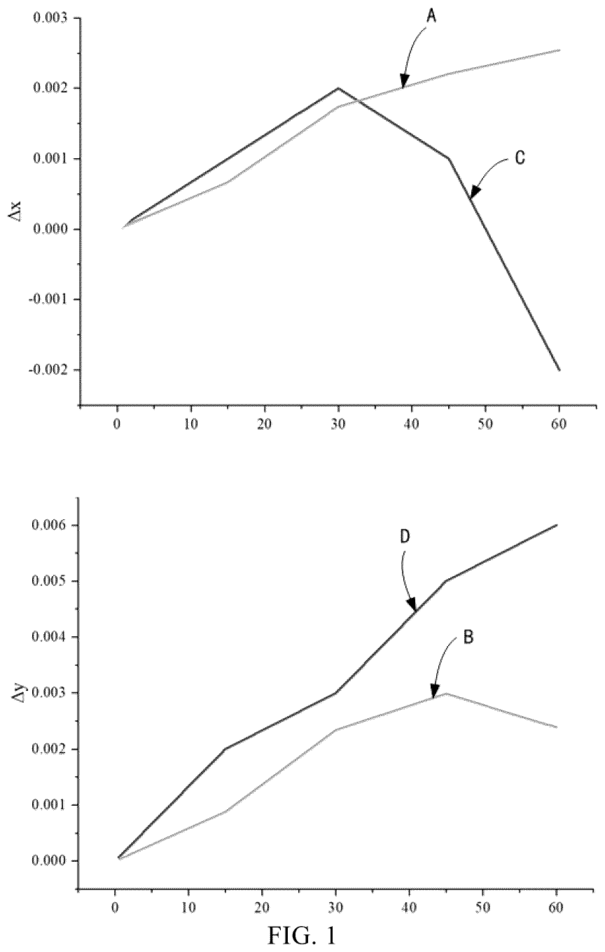

In view of the problem that there is a wide viewing angle chromaticity difference between the LED light bar and the LCD, which may lead to the LED light bar appearing relatively blue at wide viewing angles compared to the LCD, the inventors discovered the technical solution described below. Referring to FIG. 1, FIG. 1 provides a schematic comparison diagram of chromaticity difference and viewing angle curves for LED and LCD. In FIG. 1, curve A represents the trend of the chromaticity difference Δx of the LCD changing with the viewing angle, curve B represents the trend of the chromaticity difference Δy of the LCD changing with the viewing angle, curve C represents the trend of the chromaticity difference Δx of the LED changing with the viewing angle, and curve D represents the trend of the chromaticity difference Δy of the LED changing with the viewing angle. The horizontal axis in FIG. 1 indicates the viewing angle in degrees, while the vertical axis indicates the value of the chromaticity difference. Chromaticity difference refers to the deviation in chroma at varying viewing angles compared to the chroma at a direct 0° viewing angle. For example, the chromaticity difference at a 60° viewing angle signifies the deviation between the chroma at a 60° viewing angle and the chroma at a direct 0° viewing angle. The chromaticity difference is also referred to as chroma discrepancy or color shift.

As can be seen from FIG. 1, with the increase of viewing angle, the chromaticity difference Δx of LCD gradually increases, and the chromaticity difference Δy of LCD increases first and then decreases. With the increase of viewing angle, the chromaticity difference Δx of LED increases first and then decreases, and the chromaticity difference Δy of LED gradually increases. The trend of chromaticity difference of LED changing with viewing angle is inconsistent with that of LCD changing with viewing angle, which results in wide viewing angle chromaticity difference between the LED light bar and the LCD device at the same viewing angle, leading to the LED light bar appearing relatively blue at wide viewing angles compared to the LCD device.

Therefore, the inventors of the present disclosure propose a splicing display module, a method for improving color shift of the splicing display module, and a splicing screen.

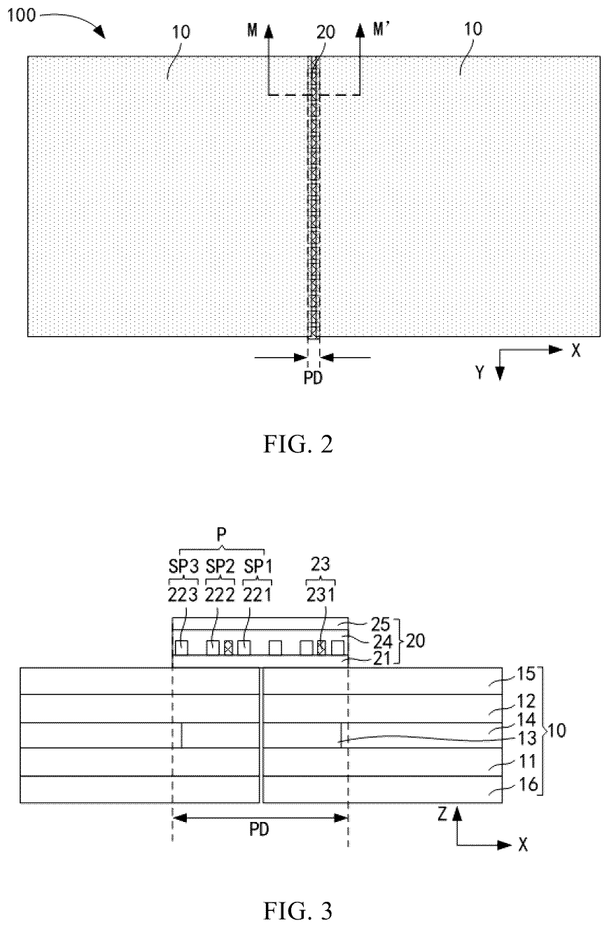

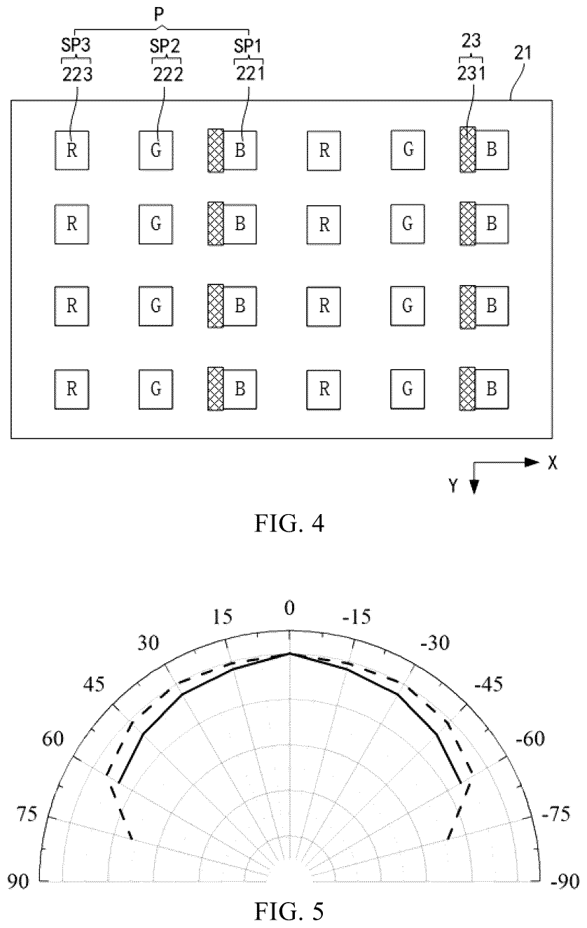

Please refer to FIGS. 1 to 5, FIG. 2 is a schematic view of a planar structure of a splicing display module provided by an embodiment of the present disclosure. FIG. 3 is a schematic cross-sectional structural view of FIG. 2 in a direction M-M′. FIG. 4 is a first schematic view of a planar structure of an arrangement of light shielding members provided by an embodiment of the present disclosure. FIG. 5 is a schematic diagram of luminance of the second display panel in FIG. 2 at various viewing angles. Referring to FIG. 2, the splicing display module 100 includes at least two first display panels 10 and at least one second display panel 20. Two adjacent first display panels 10 are spliced to each other to form a splicing area PD. The second display panel 20 is provided corresponding to the splicing area PD. The second display panel 20 is provided in the splicing area PD so that the splicing area PD may display a picture, thereby eliminating a splicing gap of the splicing display module 100 and improving a visual display effect.

The first display panel 10 includes a liquid crystal display panel or the like, and the second display panel 20 includes a LED display panel, a micro light-emitting diode (Micro-LED) display panel, a mini light-emitting diode (Mini-LED) display panel or the like. In the embodiments of the present disclosure, taking the first display panel 10 being a liquid crystal display panel and the second display panel 20 being a micro-LED display panel as an example, but the present disclosure is not limited thereto. In addition, FIG. 2 exemplarily shows that two first display panels 10 are spliced with each other, but the present disclosure is not limited thereto. For example, the splicing display module 100 in the present disclosure may further include four, six, eight, or more of the first display panels 10 spliced together, and one of the second display panels 20 is provided between every two first display panels 10 spliced with each other.

Referring to FIG. 3, the second display panel 20 includes a driving substrate 21 and at least one light-emitting pixel P provided on the driving substrate 21. The light-emitting pixel P includes a first sub-pixel SP 1 that emits blue light, a second sub-pixel SP 2 that emits green light, and a third sub-pixel SP 3 that emits red light. The first sub-pixel SP 1 includes a first light-emitting element 221, the second sub-pixel SP 2 includes a second light-emitting element 222, and the third sub-pixel SP 3 includes a third light-emitting element 223.

A plurality of driving circuits for driving corresponding light-emitting elements to emit light is provided on the driving substrate 21. The first light-emitting element 221, the second light-emitting element 222, and the third light-emitting element 223 may emit light of the same color or emit light of different colors, respectively. For example, the first light-emitting element 221, the second light-emitting element 222, and the third light-emitting element 223 may all be blue LED chips, or the first light-emitting element 221, the second light-emitting element 222, and the third light-emitting element 223 may be blue LED chip, green LED chip, and red LED chip, respectively.

The second display panel 20 further includes a light shielding member 23 provided on the driving substrate 21. The light shielding member 23 includes a first light shielding portion 231 provided on a side of the first light-emitting element 221. The first light shielding portion 231 and the first light-emitting element 221 are alternately arranged in a first direction X. The first light shielding portion 231 may block the light at wide viewing angles emitted by the first light-emitting element 221, thereby limiting the light at wide viewing angles emitted by the first sub-pixel SP1 emitting blue light. This will adjust the chromaticity of the second display panel 20 at wide viewing angles in the first direction X to match the law in which chromaticity differences of the first display panel 10 at wide viewing angles in the first direction X change with viewing angles. Consequently, the wide viewing angle chromaticity difference between the second display panel 20 and the first display panel 10 is reduced, addressing the issue where the LED light bar appears relatively blue at wide viewing angles compared to the LCD device due to the wide viewing angle chromaticity difference between the two.

The first direction X is a horizontal direction. Naturally, in some embodiments, the first direction X may be a vertical direction. Since the horizontal viewing angle range is generally larger than the vertical viewing angle range, resulting in the color shift in the horizontal viewing angle direction being greater than that in the vertical viewing angle direction, the embodiments of the present disclosure preferably improve the color shift in the horizontal viewing angle direction. That is, the first direction X is preferably a horizontal direction, but the present disclosure is not limited thereto.

Specifically, continuing to refer to FIG. 3, the first display panel 10 includes a first substrate 11 and a second substrate 12 opposite to each other, a liquid crystal layer 14 disposed between the first substrate 11 and the second substrate 12, and a frame adhesive 13 surrounding the liquid crystal layer 14. The first substrate 11, the liquid crystal layer 14, and the second substrate 12 are arranged sequentially in the thickness direction Z of the splicing display module 100. The first substrate 11 is an array substrate, and the second substrate 12 is a color filter substrate. The first display panel 10 further includes a first polarizer 15 provided on a side of the second substrate 12 away from the first substrate 11, and a second polarizer 16 provided on a side of the first substrate 11 away from the second substrate 12.

The second display panel 20 further includes an encapsulation layer 24 covering the first light-emitting element 221, the second light-emitting element 222, the third light-emitting element 223, and the light shielding member 23, and the encapsulation layer 24 is used for protecting the respective light-emitting elements. The material of the encapsulation layer 24 includes epoxy resin or the like. The material of the light shielding member 23 includes a material having a light shielding function, such as a light shielding ink or the like.

In the thickness direction Z of the splicing display module 100, the height of the light shielding member 23 is less than or equal to the height of the first light-emitting element 221, so as to avoid excessive influence on the light emitted from the front of the first light-emitting element 221. Of course, the present disclosure is not limited thereto. In some other embodiments, when the color shift difference between the second display panel 20 and the first display panel 10 is large, the height of the light shielding member 23 may be greater than the height of the first light-emitting element 221.

Optionally, the second display panel 20 further includes a privacy protection film 25 provided on a side of the first light-emitting element 221 away from the driving substrate 21. For example, the privacy protection film 25 may be disposed on a side of the encapsulation layer 24 away from the driving substrate 21, and is used to adjust the lightness of the second display panel 20 at a wide viewing angle.

In an embodiment, referring to FIGS. 3 and 4, the first light-emitting element 221, the second light-emitting element 222, and the third light-emitting element 223 are sequentially arranged in the first direction X. A plurality of the first light-emitting elements 221 are arranged at intervals in the second direction Y. A plurality of the second light-emitting elements 222 are arranged at intervals in the second direction Y. A plurality of the third light-emitting elements 223 are arranged at intervals in the second direction Y. The second direction Y intersects with the first direction X. For example, If the first direction X is horizontal, the second direction Y is vertical.

It should be noted that, in the schematic planar arrangement view of the light-emitting elements in the present disclosure, as shown in FIG. 4, for the purpose of clearly differentiating the light-emitting elements, the first light-emitting element 221, the second light-emitting element 222, and the third light-emitting element 223 are denoted as B, G, and R, respectively.

Referring to FIG. 4, the first light shielding portion 231 is provided on a side of the first light-emitting element 221. The side of the first light-emitting element 221 close to the third light-emitting element 223 is not provided with the light shielding member 23 to avoid affecting the light emission of the third light-emitting element 223. The light shielding member 23 is not provided on the peripheral side of the third light-emitting element 223 to avoid affecting the light emission of the third light-emitting element 223. The first light shielding portion 231 is located on the side of the first light-emitting element 221 close to the second light-emitting element 222, and covers the side surface of the first light-emitting element 221 close to the second light-emitting element 222 to shield light emitted from the side surface of the first light-emitting element 221, which may reduce light emission at a wide viewing angle of the first sub-pixel SP1. As shown in FIG. 5, the solid line in FIG. 5 indicates the brightness change of the first sub-pixel SP1 at each viewing angle after the light shielding member 23 is provided, and the dotted line in FIG. 5 indicates the brightness change of the first sub-pixel SP1 at each viewing angle in the case where the light shielding member 23 is not provided, and it may be seen from FIG. 5 that the brightness of the first sub-pixel SP1 at each viewing angle decreases after the light shielding member 23 is provided.

In this manner, during the light mixing process of the first sub-pixel SP1 with the second sub-pixel SP2 and the third sub-pixel SP3, the proportion of the first sub-pixel SP1 is reduced, and the proportion of the second sub-pixel SP2 and the proportion of the third sub-pixel SP3 are increased, achieving a dot tuning effect to adjust the chroma of the second display panel 20 at a wide viewing angle in the first direction X, to match the law that the chromaticity difference of the first display panel 10 at a wide viewing angle in the first direction X changes with the viewing angle, so that the wide viewing angle chromaticity difference between the second display panel 20 and the first display panel 10 may be reduced.

Optionally, the length of the light shielding member 23 in the second direction Y is greater than or equal to the length of the corresponding light-emitting element in the second direction Y. The length of the light shielding member 23 beyond the corresponding light-emitting element is less than half of the distance between the light-emitting element and the adjacent light-emitting element in the second direction Y, and the length can be, for example, ⅓, ¼, or ⅕, so as to better shield the corresponding light-emitting element and avoid affecting light emission of the adjacent light-emitting element.

For example, the length of the first light shielding portion 231 in the second direction Y is greater than or equal to the length of the corresponding first light-emitting element 221 in the second direction Y. The length of the first light shielding portion 231 beyond the first light-emitting element 221 is less than half of the distance between two adjacent first light-emitting elements 221, so as to better shield the first light-emitting element 221 and avoid affecting light emission of the adjacent second light-emitting element 222.

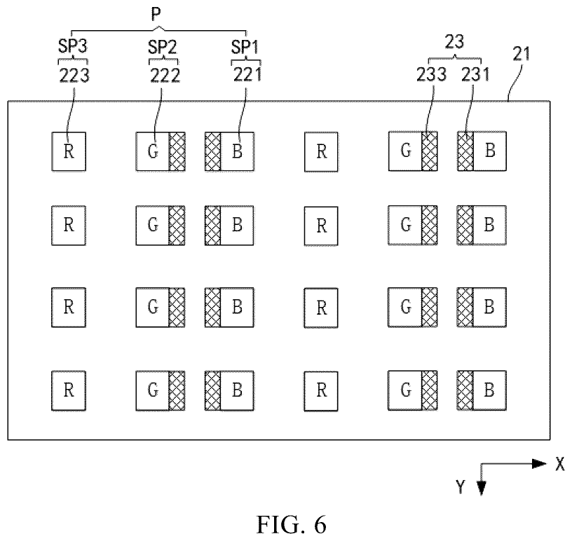

In an embodiment, referring to FIGS. 1 to 6, FIG. 6 is a second schematic view of a planar structure of an arrangement of the light shielding members 23 provided by an embodiment of the present disclosure. Referring to FIG. 6, the difference in the arrangement of the light shielding member 23 compared to the example in FIG. 4 is that the light shielding member 23 further includes a third light shielding portion 233 disposed on a side of the second light-emitting element 222, and the third light shielding portion 233 and the second light-emitting element 222 are sequentially arranged in the first direction X. The third light shielding portion 233 and the first light shielding portion 231 are located between the first light-emitting element 221 and the second light-emitting element 222. The third light shielding portion 233 is located on a side of the second light-emitting element 222 close to the first light-emitting element 221 to block light emitting from the side of the second light-emitting element 222, so as to further match the law in which the wide viewing angle chromaticity difference of the first display panel 10 in the first direction X changes with the viewing angle, and further reduce the color shift difference between the second display panel 20 and the first display panel 10 at the same viewing angle in the first direction X. The side of the second light-emitting element 222 close to the third light-emitting element 223 is not provided with the light shielding member 23 to avoid affecting light emission of the third light-emitting element 223.

Optionally, the third light shielding portion 233 may be spaced apart from the first light shielding portion 231, and the heights of the third light shielding portion 233 and the first light shielding portion 231 may be the same or different, depending on the required adjustment to reduce the color shift difference between the second display panel 20 and the first display panel 10. Please refer to the embodiments mentioned above for additional explanations, which will not be reiterated here.

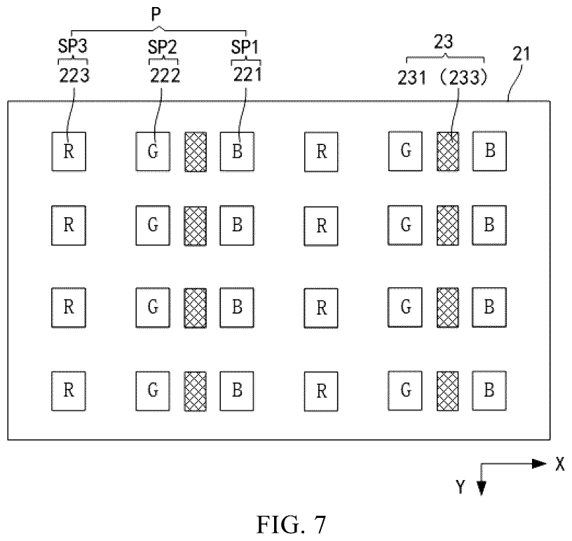

In an embodiment, referring to FIGS. 1 to 7, FIG. 7 is a third schematic view of a planar structure of an arrangement of the light shielding members 23 provided by an embodiment of the present disclosure. Referring to FIG. 7, the difference in the arrangement of the light shielding member 23 compared to the example in FIG. 6 is that the first light shielding portion 231 and the third light shielding portion 233 are integrally configured. This not only reduces the color shift difference between the second display panel 20 and the first display panel 10 but also simplifies the process design and lowers the difficulty of setting up the light shielding members 23. Please refer to the embodiments mentioned above for additional explanations, which will not be reiterated here.

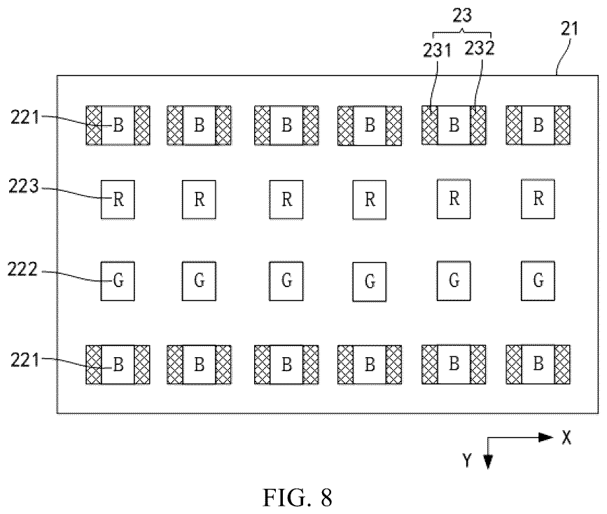

In an embodiment, referring to FIGS. 1 to 8, FIG. 8 is a fourth schematic view of a planar structure of an arrangement of the light shielding members 23 provided by an embodiment of the present disclosure. Referring to FIG. 8, the difference in the arrangement of the light shielding member 23 compared to the example in FIG. 4 is that the first light-emitting element 221, the second light-emitting element 222, and the third light-emitting element 223 are sequentially arranged in the second direction Y. A plurality of first light-emitting elements 221 are arranged in the first direction X. A plurality of second light-emitting elements 222 are arranged in the first direction X. A plurality of third light-emitting elements 223 are arranged in the first direction X. The light shielding member 23 further includes a second light shielding portion 232 located on the other side of the first light-emitting element 221, and the first light-emitting element 221 is located between the first light shielding portion 231 and the second light shielding portion 232 in the first direction X. The specific design of the second light shielding portion 232 may refer to the design of the first light shielding portion 231.

The first light shielding portion 231 and the second light shielding portion 232 are disconnected from each other, that is, no other light shielding member 23 is provided between the first light shielding portion 231 and the second light shielding portion 232, and the first light shielding portion 231 and the second light shielding portion 232 are not connected to each other, so as to avoid affecting light emission of the third light-emitting element 223 adjacent to the first light-emitting element 221. Please refer to the embodiments mentioned above for additional explanations, which will not be reiterated here.

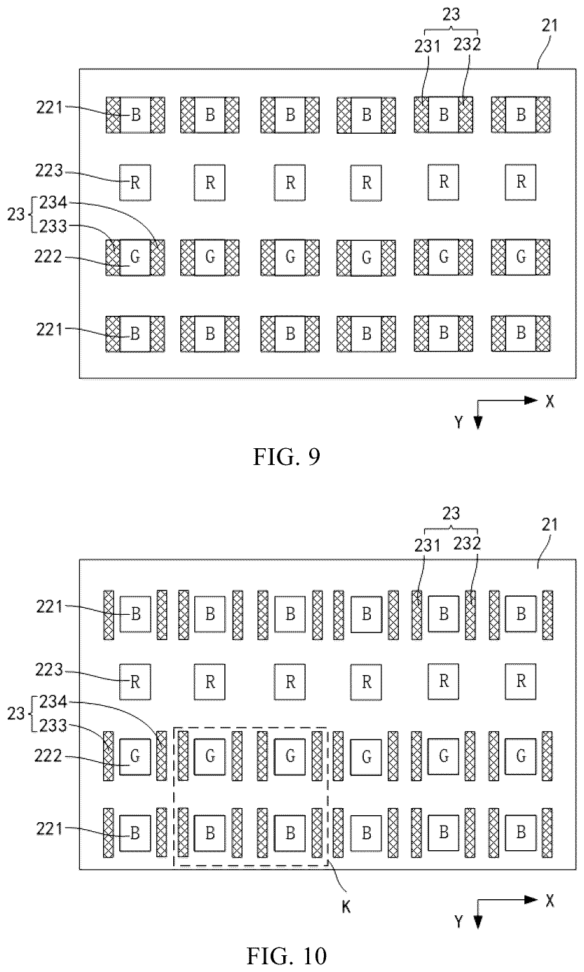

In an embodiment, referring to FIGS. 1 to 9, FIG. 9 is a fifth schematic view of a planar structure of an arrangement of the light shielding members 23 provided by an embodiment of the present disclosure. Referring to FIG. 9, the difference in the arrangement of the light shielding member 23 compared to the example in FIG. 8 lies in that the light shielding member 23 further includes a third light shielding portion 233 disposed on a side of the second light-emitting element 222 and a fourth light shielding portion 234 disposed on the other side of the second light-emitting element 222. The second light-emitting element 222 is located between the third light shielding portion 233 and the fourth light shielding portion 234 in the first direction X. The third light shielding portion 233 is disposed corresponding to the first light shielding portion 231 in the second direction Y. The fourth light shielding portion 234 is disposed corresponding to the second light shielding portion 232 in the second direction Y. This further matches the law in which the chromaticity difference of the first display panel 10 in the first direction X change with the viewing angle, and further reduces the color shift difference between the second display panel 20 and the first display panel 10 at the same viewing angle in the first direction X. Please refer to the embodiments mentioned above for additional explanations, which will not be reiterated here.

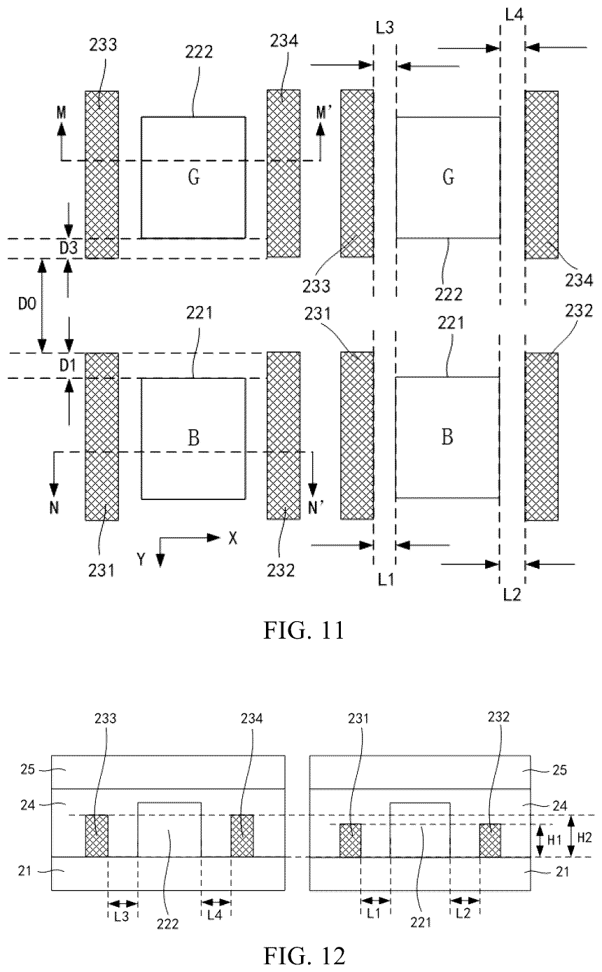

In an embodiment, referring to FIGS. 1 to 12, FIG. 10 is a sixth schematic view of a planar structure of an arrangement of the light shielding members provided by an embodiment of the present disclosure. FIG. 11 is a detailed structural schematic view at K in FIG. 10. FIG. 12 is a schematic cross-sectional structural view along directions M-M′ and N-N′ in FIG. 11. Referring to FIG. 10, the difference in the arrangement of the light shielding member 23 compared to the example in FIG. 9 is that the first light shielding portion 231, the second light shielding portion 232, the third light shielding portion 233, and the fourth light shielding portion 234 all have gaps with the corresponding light-emitting elements. This ensures light shielding for the light-emitting elements while reducing the difficulty of manufacturing the light shielding member.

Specifically, referring to FIG. 11, the first light shielding portion 231 is spaced apart from the first light-emitting element 221 at a first interval L1. The second light shielding portion 232 is spaced apart from the first light-emitting element 221 at a second interval L2. The third light shielding portion 233 is spaced apart from the second light-emitting element 222 at a third interval L3. The fourth light shielding portion 234 is spaced apart from the second light-emitting element 222 at a fourth interval L4. The first interval L1, the second interval L2, the third interval L3, and the fourth interval L4 are all greater than or equal to 0 um and less than or equal to 90 um, such as 0 μm, 5 μm, 10 μm, 15 μm, 20 μm, 25 μm, 30 μm, 40 μm, 50 μm, 60 μm, 70 μm, 80 μm, 90 μm, or the like.

In the second direction Y, the length of each light shielding portion is greater than or equal to the length of the corresponding light-emitting element, so as to further reduce the difficulty of manufacturing the light shielding member while satisfying the requirement of light-shielding the light-emitting element. Specifically, the length of the first light shielding portion 231 is greater than or equal to the length of the first light-emitting element 221. The length of the second light shielding portion 232 is greater than or equal to the length of the first light-emitting element 221. The length of the third light shielding portion 233 is greater than or equal to the length of the second light-emitting element 222. The length of the fourth light shielding portion 234 is greater than or equal to the length of the second light-emitting element 222.

Referring to FIG. 11, taking the first light shielding portion 231 and the third light shielding portion 233 as examples, in the second direction Y, the length of the first light shielding portion 231 is greater than the length of the first light-emitting element 221, so that the first light shielding portion 231 completely covers the side surface of the first light-emitting element 221 in the second direction Y and extends beyond the side surface of the first light-emitting element 221. The length D1 by which the first light shielding portion 231 extends beyond the side surface of the first light-emitting element 221 is less than the pixel gap D0 between the first light-emitting element 221 and an adjacent second light-emitting element 222 or third light-emitting element. Furthermore, D1<½*D0, for example, D1≤⅓*D0, D1≤¼*D0, or D1≤⅕*D0, etc. This configuration ensures that the first light shielding portion 231 blocks the light emitted by the first light-emitting element 221 while simultaneously reducing the difficulty of manufacturing the light shielding member and avoiding interference with the light emission of adjacent light-emitting elements.

Accordingly, in the second direction Y, the length of the third light shielding portion 233 is greater than the length of the second light-emitting element 222, so that the third light shielding portion 233 completely covers the side surface of the second light-emitting element 222 in the second direction Y and extends beyond the side surface of the second light-emitting element 222. The length D1 by which the third light shielding portion 233 extends beyond the side surface of the second light-emitting element 222 is less than the pixel gap D0 between the second light-emitting element 222 and the adjacent first light-emitting element 221 or third light-emitting element. Furthermore, D1<½*D0, such as D1≤⅓*D0, D1≤¼*D0, or D1≤⅕*D0, etc. This configuration ensures that the third light shielding portion 233 blocks the light emitted by the second light-emitting element 222 while simultaneously reducing the difficulty of manufacturing the light shielding member and avoiding interference with the light emission of adjacent light-emitting elements.

Referring to FIG. 12, the third light shielding portion 233 has the same height as the fourth light shielding portion 234. The second light shielding portion 232 has the same height as the first light shielding portion 231. The height H1 of the first light shielding portion 231 is less than the height of the first light-emitting element 221. The height H2 of the third light shielding portion 233 is less than the height of the second light-emitting element 222. The height H1 of the first light shielding portion 231 is less than the height H2 of the third light shielding portion 233, and for example, if the heights of the first light-emitting element 221 and the second light-emitting element 222 are both 120 um, the height of the first light shielding portion 231 is 71 um, the height of the third light shielding portion 233 is 80 um, and the first interval L1 and the third interval L3 is both 80 um. By adjusting the height difference between the first light shielding portion 231 and the third light shielding portion 233, the chromaticity of the second display panel 20 at the wide viewing angle in the first direction X may be better adjusted to better match the law in which the chromaticity difference of the first display panel 10 at the wide viewing angle in the first direction X changes with the viewing angle, and further reduce the chromaticity difference of the wide viewing angle between the second display panel 20 and the first display panel 10. Please refer to the embodiments mentioned above for additional explanations, which will not be reiterated here.

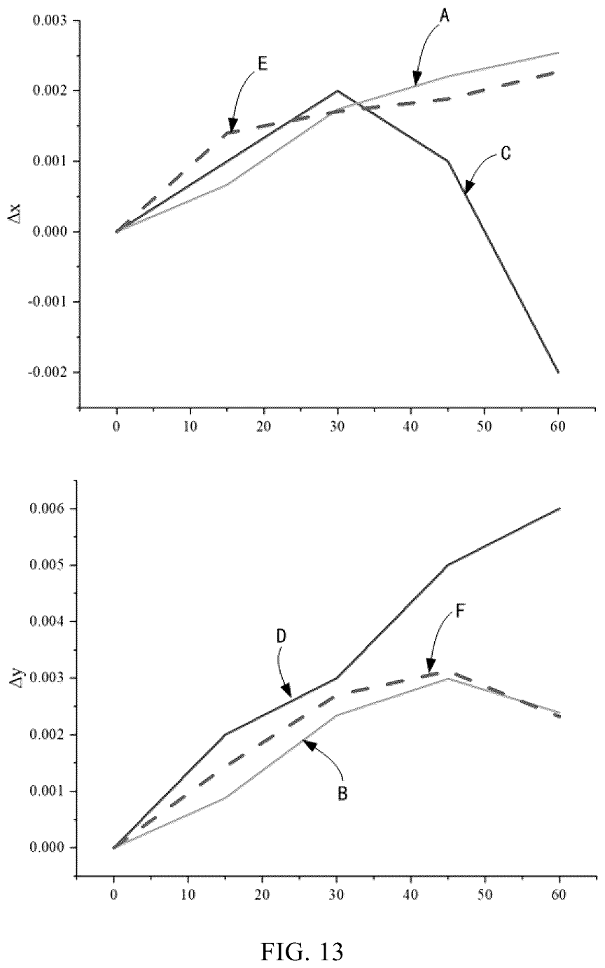

Hereinafter, the matching degree of the wide viewing angle chromaticity difference between the second display panel and the first display panel in the first direction with the viewing angle change in the present disclosure is verified by the arrangement of the light shielding members illustrated in FIG. 10. Referring to FIG. 13, FIG. 13 is a schematic diagram showing a chromaticity difference viewing angle curve comparison between a second display panel and a first display panel provided by an embodiment of the present disclosure. In FIG. 13, curve A represents the trend of the chromaticity difference Δx of the first display panel changing with the viewing angle. Curve B represents the trend of the chromaticity difference Δy of LCD changing with the viewing angle. Curve C represents the trend of the chromaticity difference Δx of LED display panel without any light shielding member changing with the viewing angle. Curve D represents the trend of the chromaticity difference Δy of the LED display panel without any light shielding member changing with the viewing angle, Curve E represents the trend of the chromaticity difference Δx of the second display panel changing with the viewing angle. Curve F represents the trend of the chromaticity difference Δy of the second display panel changing with the viewing angle. In FIG. 13, the abscissa represents the angle of the viewing angle, and the ordinate represents the value of the chromaticity difference. The chromaticity difference refers to the difference of the chromaticity at different viewing angles with respect to the front view of 0°. For example, the chromaticity difference at a viewing angle of 60° refers to the difference between the chromaticity at the viewing angle of 60° and the chromaticity at the front view of 0°, and the chromaticity difference is also referred to as chroma discrepancy or color shift.

As can be seen from FIG. 13, the chromaticity differences Δx and Δy of the LED display panel without the light shielding member and the first display panel show inconsistent trends with changes in viewing angle. However, the chromaticity differences Δx and Δy of the second display panel and the first display panel show consistent trends with changes in viewing angle in the present disclosure, and the law in which the chromaticity difference of the second display panel at wide viewing angle changes with the viewing angle is the same as that of the chromaticity difference of the first display panel at the wide viewing angle in the first direction X changes with the viewing angle. Consequently, the wide viewing angle chromaticity difference between the second display panel and the first display panel is reduced, addressing the issue where the LED light bar appears relatively blue at wide viewing angles compared to the LCD device due to the chromaticity difference between the two.

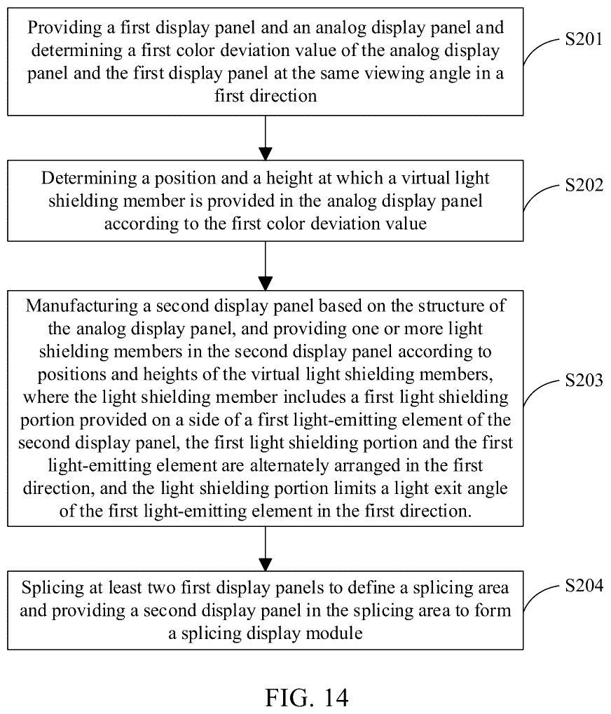

Based on the same inventive concept, an embodiment of the present disclosure further provides a method of improving color shift of a splicing display module. Referring to FIGS. 1 to 14, FIG. 14 is a schematic flow diagram of a method for improving color shift of a splicing display module provided by an embodiment of the present disclosure. Referring to FIG. 14, the method of improving the color shift of the splicing display module includes the following steps S201 to S204.

At step S201, a first display panel and an analog display panel are provided, and a first color deviation value of the analog display panel and the first display panel at the same viewing angle in a first direction is determined.

Specifically, the step of determining a first color deviation value of the analog display panel and the first display panel at the same viewing angle in the first direction includes the following steps S2011 to S2014.

At step S2011, the chromaticity of the first display panel at each viewing angle in the first direction is obtained, and a first chromaticity difference viewing angle curve is generated.

Specifically, referring to FIG. 13, the chromaticity of the first display panel at each viewing angle in the first direction is measured and the chromaticity difference at each viewing angle is calculated, so that a first chromaticity difference viewing angle curve is drawn, shown as the curve A and the curve B in FIG. 13.

At step S2012, the brightness and the chromaticity of the analog display panel at a positive viewing angle are adjusted to be consistent with the brightness and the chromaticity of the first display panel at the positive viewing angle.

At step S2013, the chromaticity of the analog display panel at each viewing angle in the first direction is obtained, and a second chromaticity difference viewing angle curve is generated.

Specifically, referring to FIG. 13, the chromaticity of the analog display panel at each viewing angle in the first direction is measured and the chromaticity difference at each viewing angle is calculated, so that a second chromaticity difference viewing angle curve is drawn, shown as the curve C and the curve D in FIG. 13. The analog display panel is an LED display panel without the light shielding member.

At step S2014, the first chromaticity difference viewing angle curve and the second chromaticity difference viewing angle curve are compared to obtain the first color deviation value between the analog display panel and the first display panel at the same viewing angle in the first direction.

Specifically, referring to FIG. 13, a difference value of the chromaticity difference between the analog display panel and the first display panel at each viewing angle is determined according to the first chromaticity difference viewing angle curve and the second chromaticity difference viewing angle curve in FIG. 13, and the difference value of the chromaticity difference is the first color deviation value.

At step S202, a position and a height at which a virtual light shielding member is provided in the analog display panel are determined according to the first color deviation value.

Specifically, the step of determining a position and a height at which a virtual shielding member is provided in the analog display panel according to the first color deviation value includes the following steps S2021 to S2023.

At step S2021, a target chromaticity of each viewing angle of the analog display panel in the first direction is determined according to the first color deviation value.

Specifically, a chromaticity value to be adjusted in each viewing angle of the analog display panel is obtained according to the first color deviation value, and the chromaticity value to be adjusted is the chromaticity value to be compensated, and the chromaticity value to be compensated plus a chromaticity value deviating from the corresponding viewing angle is a target chromaticity.

At step S2022, a brightness ratio of each viewing angle of the analog display panel in the first direction is determined according to the target chromaticity.

Specifically, the brightness ratio at the corresponding viewing angle is obtained according to the target chromaticity, and the brightness ratio includes brightness of a sub-pixel emitting red light, a sub-pixel emitting green light, and a sub-pixel emitting blue light.

At step S2023, the position and the height at which a virtual light shielding member is provided in the analog display panel are determined according to the brightness ratio.

Specifically, the light emitted by some sub-pixels may be blocked by providing one or more virtual light shielding members based on the brightness ratios of various viewing angles. For example, the position and height of the virtual light shielding member may be adjusted to adjust the proportion of the blocked sub-pixels in the mixed light, so as to reach the target chromaticity, thereby determining the position and height of the virtual light shielding member.

At step S203, a second display panel is manufactured based on the structure of the analog display panel, and one or more light shielding members in the second display panel are provided according to positions and heights of the virtual light shielding members. The light shielding member includes a first light shielding portion provided on a side of a first light-emitting element of the second display panel, the first light shielding portion and the first light-emitting element are alternately arranged in the first direction, and the light shielding portion limits a light exit angle of the first light-emitting element in the first direction.

At step S204, at least two first display panels are spliced with each other to form a splicing area, and a second display panel in the splicing area is provided to form a splicing display module.

Based on the same inventive concept, an embodiment of the present disclosure further provides a splicing screen, and the splicing screen includes the splicing display module 100 of any one of the foregoing embodiments.

In summary, the present disclosure provides a splicing display module and a method of improving color shift of the splicing display module, and a splicing screen. The splicing display module includes at least two first display panels and a second display panel, and the two adjacent first display panels are spliced with each other to form a splicing area. The second display panel is disposed corresponding to the splicing area. A first light shielding portion is provided on a side of the first light-emitting element of the second display panel. The first light shielding portion and the first light-emitting element are alternately arranged in the first direction. The first light shielding portion may block the light at wide viewing angles emitted by the first light-emitting element, thereby limiting the light at wide viewing angles emitted by the first sub-pixel. This adjustment modifies the chromaticity of the second display panel at wide viewing angles in the first direction to match the law in which chromaticity differences of the first display panel in the first direction change with viewing angles. Consequently, the wide viewing angle chromaticity difference between the second display panel and the first display panel is reduced, addressing the issue where the LED light bar appears bluish at wide viewing angles compared to the LCD device due to the chromaticity difference between the two.

In the above-mentioned embodiments, the description of each embodiment has its own emphasis, and parts not described in detail in a certain embodiment can be referred to the related description of other embodiments.

The embodiments of the present disclosure have been described in detail above, and the principles and embodiments of the present disclosure have been described herein by applying specific examples, and the description of the above embodiments is only for helping to understand the technical solutions and core ideas of the present disclosure. Ordinary skilled in the art should understand that they can modify the technical solutions described in the aforementioned embodiments, or equivalently replace some of the technical features, which do not deviate from the essence of the corresponding technical solutions from the scope of the technical solutions of the various embodiments of the present disclosure.

What is claimed is:

1. A splicing display module, comprising:
at least two first display panels, two adjacent ones of the first display panels being spliced with each other to form a splicing area; and
a second display panel disposed corresponding to the splicing area, the second display panel comprising a driving substrate and at least one light-emitting pixel disposed on the driving substrate, the light-emitting pixel comprising a first sub-pixel emitting blue light, and the first sub-pixel comprising a first light-emitting element;
wherein the second display panel further comprises a light shielding member disposed on the driving substrate, the light shielding member comprises a first light shielding portion disposed on a side of the first light-emitting element, the first light shielding portion and the first light-emitting element are alternately arranged in a first direction, and the first light shielding portion limits a light exit angle of the first light-emitting element in the first direction.

2. The splicing display module of claim 1, wherein the light-emitting pixel further comprises a second sub-pixel emitting green light and a third sub-pixel emitting red light, the second sub-pixel comprises a second light-emitting element, the third sub-pixel comprises a third light-emitting element, wherein the first light-emitting element, the second light-emitting element, and the third light-emitting element are sequentially arranged in a second direction, and the second direction intersects the first direction; and
the light shielding member further comprises a second light shielding portion located on another side of the first light-emitting element, and the first light-emitting element is located between the first light shielding portion and the second light shielding portion in the first direction.

3. The splicing display module of claim 2, wherein the light shielding member further comprises a third light shielding portion disposed on a side of the second light-emitting element, the third light shielding portion and the second light-emitting element are alternately arranged in the first direction, and the third light shielding portion is disposed correspondingly to the first light shielding portion in the second direction.

4. The splicing display module of claim 3, wherein the light shielding member further comprises a fourth light shielding portion disposed on another side of the second light-emitting element, the second light-emitting element is located between the third light shielding portion and the fourth light shielding portion in the first direction, and the fourth light shielding portion is disposed correspondingly to the second light shielding portion in the second direction.

5. The splicing display module of claim 4, wherein the third light shielding portion has the same height as the fourth light shielding portion, the second light shielding portion has the same height as the first light shielding portion, and a height of the first light shielding portion is less than a height of the third light shielding portion.

6. The splicing display module of claim 4, wherein the first light shielding portion is spaced apart from the first light-emitting element at a first interval, the second light shielding portion is spaced apart from the first light-emitting element at a second interval, the third light shielding portion is spaced apart from the second light-emitting element at a third interval, and the fourth light shielding portion is spaced apart from the second light-emitting element at a fourth interval, and the first interval, the second interval, the third interval, and the fourth interval are all greater than or equal to 0 um and less than or equal to 90 um.

7. The splicing display module of claim 4, wherein in the second direction, a length of the first light shielding portion is greater than or equal to a length of the first light-emitting element, a length of the second light shielding portion is greater than or equal to a length of the first light-emitting element, a length of the third light shielding portion is greater than or equal to a length of the second light-emitting element, and a length of the fourth light shielding portion is greater than or equal to a length of the second light-emitting element.

8. The splicing display module of claim 1, wherein the light-emitting pixel further comprises a second sub-pixel emitting green light and a third sub-pixel emitting red light, the second sub-pixel comprises a second light-emitting element, the third sub-pixel comprises a third light-emitting element, the first light-emitting element, the second light-emitting element, and the third light-emitting element are sequentially arranged in the first direction; and
the light shielding member further comprises a third light shielding portion disposed on a side of the second light-emitting element, and both the third light shielding portion and the first light shielding portion are located between the first light-emitting element and the second light-emitting element.

9. The splicing display module of claim 8, wherein the first light shielding portion and the third light shielding portion are integrally provided.

10. The splicing display module of claim 1, wherein a height of the light shielding member is less than or equal to a height of the first light-emitting element.

11. The splicing display module of claim 10, wherein the second display panel further comprises a privacy protection film disposed on a side of the first light-emitting element away from the driving substrate.

12. A splicing screen, comprising a splicing display module, wherein the splicing display module comprises:
at least two first display panels, two adjacent ones of the first display panels being spliced with each other to form a splicing area; and
a second display panel disposed corresponding to the splicing area, the second display panel comprising a driving substrate and at least one light-emitting pixel disposed on the driving substrate, the light-emitting pixel comprising a first sub-pixel emitting blue light, and the first sub-pixel comprising a first light-emitting element;
wherein the second display panel further comprises a light shielding member disposed on the driving substrate, the light shielding member comprises a first light shielding portion disposed on a side of the first light-emitting element, the first light shielding portion and the first light-emitting element are alternately arranged in a first direction, and the first light shielding portion limits a light exit angle of the first light-emitting element in the first direction.

13. The splicing screen of claim 12, wherein the light-emitting pixels further comprise a second sub-pixel emitting green light and a third sub-pixel emitting red light, the second sub-pixel comprises a second light-emitting element, the third sub-pixel comprises a third light-emitting element, the first light-emitting element, the second light-emitting element, and the third light-emitting element are sequentially arranged in a second direction, and the second direction intersects the first direction; and
the light shielding member further comprises a second light shielding portion located on another side of the first light-emitting element, and the first light-emitting element is located between the first light shielding portion and the second light shielding portion in the first direction.

14. The splicing screen of claim 13, wherein the light shielding member further comprises a third light shielding portion disposed on one side of the second light-emitting element, the third light shielding portion and the second light-emitting element are alternately arranged in a first direction, and the third light shielding portion is disposed correspondingly to the first light shielding portion in the second direction.

15. The splicing screen of claim 14, wherein the light shielding member further comprises a fourth light shielding portion disposed on the other side of the second light-emitting element, the second light-emitting element is located between the third light shielding portion and the fourth light shielding portion in the first direction, and the fourth light shielding portion is disposed correspondingly to the second light shielding portion in the second direction.

16. The splicing screen of claim 15, wherein the third light shielding portion has the same height as the fourth light shielding portion, the second light shielding portion has the same height as the first light shielding portion, and the height of the first light shielding portion is less than a height of the third light shielding portion.

17. The splicing screen of claim 15, wherein the first light shielding portion is spaced apart from the first light-emitting element at a first interval, the second light shielding portion is spaced apart from the first light-emitting element at a second interval, the third light shielding portion is spaced apart from the second light-emitting element at a third interval, and the fourth light shielding portion is spaced apart from the second light-emitting element at a fourth interval, and the first interval, the second interval, the third interval, and the fourth interval are all greater than or equal to 0 um and less than or equal to 90 um.

18. The splicing screen of claim 15, wherein in the second direction, a length of the first light shielding portion is greater than or equal to a length of the first light-emitting element, a length of the second light shielding portion is greater than or equal to a length of the first light-emitting element, a length of the third light shielding portion is greater than or equal to a length of the second light-emitting element, and a length of the fourth light shielding portion is greater than or equal to a length of the second light-emitting element.

19. The splicing screen of claim 12, wherein the light-emitting pixels further comprise a second sub-pixel emitting green light and a third sub-pixel emitting red light, the second sub-pixel comprises a second light-emitting element, the third sub-pixel comprises a third light-emitting element, the first light-emitting element, the second light-emitting element, and the third light-emitting element are sequentially arranged in a first direction; and
the light shielding member further comprises a third light shielding portion disposed on a side of the second light-emitting element, and both the third light shielding portion and the first light shielding portion are located between the first light-emitting element and the second light-emitting element.

20. The splicing display module of claim 19, wherein the first light shielding portion and the third light shielding portion are integrally provided.
